(19) United States
(12) Patent Application Publication
(10) Pub. No.: US 2025/0062163 A1
(43) Pub. Date: Feb. 20, 2025

(54) ACOUSTIC MONITORING FOR PROCESS RELIABILITY DURING POLISHING

(71) Applicant: Applied Materials, Inc., Santa Clara, CA (US)

(72) Inventors: Nicholas A. Wiswell, Sunnyvale, CA (US); Benjamin Cherian, San Jose, CA (US); Haoquan Fang, Sunnyvale, CA (US); Jun Qian, Sunnyvale, CA (US); Thomas H. Osterheld, Mountain View, CA (US); Sohrab Pourmand, San Jose, CA (US)

(21) Appl. No.: 18/452,426

(22) Filed: Aug. 18, 2023

(51) Int. Cl. H01L 21/66; B24B 37/005

(52) U.S. Cl. CPC H01L 22/20; B24B 37/005; H01L 21/30625; H01L 21/31053; H01L 21/3212

(57) ABSTRACT

Disclosed herein is a chemical mechanical polishing apparatus, comprising a platen to support a polishing pad; a carrier head to hold a surface of a substrate against the polishing pad; a motor to generate relative motion between the platen and the carrier head so as to polish an overlying layer on the substrate; an in-situ acoustic monitoring system including an acoustic sensor that receives acoustic energy from the substrate and the polishing pad; and a controller configured to detect an abnormal acoustic event based on measurements from the in-situ acoustic monitoring system, and determine a type of anomaly based on signals measured by the in-situ acoustic monitoring system during the abnormal acoustic event.

### FIELD OF THE DISCLOSURE

The disclosure relates to chemical mechanical polishing, and more specifically to detection of abnormal events from acoustic signals received during chemical mechanical polishing.

### BACKGROUND

An integrated circuit is typically formed on a substrate by the sequential deposition of conductive, semiconductive, or insulative layers on a silicon wafer. One fabrication step involves depositing a filler layer over a non-planar surface and planarizing the filler layer. For certain applications, the filler layer is planarized until the top surface of the underlying patterned layer is exposed. For example, a conductive filler layer can be deposited on a patterned insulative layer to fill the trenches or holes in the insulative layer. After planarization, the portions of the conductive layer remaining between the raised pattern of the insulative layer form vias, plugs, and lines that provide conductive paths between thin film circuits on the substrate. For other applications, such as oxide polishing, the filler layer is planarized until a predetermined thickness is left over the non-planar surface. In addition, planarization of the substrate surface is usually required for photolithography.

Chemical mechanical polishing (CMP) is one accepted method of planarization. This planarization method typically requires that the substrate be mounted on a carrier or polishing head. The exposed surface of the substrate is typically placed against a rotating polishing pad. The carrier head provides a controllable load on the substrate to push it against the polishing pad. An abrasive polishing slurry is typically supplied to the surface of the polishing pad.

Acoustic monitoring has been proposed for monitoring the progress of the polishing process, and more particularly for detection of exposure of an underlying layer, e.g., during metal polishing to expose the underlying patterned barrier layer or dielectric layer.

### SUMMARY

In one aspect, a chemical mechanical polishing apparatus includes a carrier head to hold a substrate against a polishing pad. An in-situ acoustic monitoring system receives acoustic signals from the substrate and carrier head and generates signals which are transmitted to a controller. The controller receives the signals and generates and uses signal processing to detect discrete anomalies in the time-series acoustic emission signal. The controller is configured to change one or more polishing parameter, or generate an alert, based on the detected anomalies.

In general, an aspect disclosed herein is a chemical mechanical polishing apparatus, including a platen to support a polishing pad; a carrier head to hold a surface of a substrate against the polishing pad; a motor to generate relative motion between the platen and the carrier head so as to polish an overlying layer on the substrate; an in-situ acoustic monitoring system including an acoustic sensor that receives acoustic energy from the substrate and the polishing pad; and a controller configured to detect an abnormal acoustic event based on measurements from the in-situ acoustic monitoring system, and determine a type of anomaly based on signals measured by the in-situ acoustic monitoring system during the abnormal acoustic event.

Examples may include one or more of the following features. The controller can detect the abnormal acoustic event based on comparison of the signal to prior measurements of acoustic signals generated by friction between test substrates and the polishing pad. The detection of the abnormal acoustic event can be based on the controller determining a power spectrum of the acoustic signals; determining a difference between the power spectrum and a reference power spectrum stored in a storage device of the apparatus; and detecting the abnormal acoustic event based on the difference. The controller can be configured to store a catalog that can include a plurality of types of anomalies and at least one criterion for each type of anomaly. The at least one criterion includes a degree of similarity to a reference spectrum representative of the type of anomaly. The controller can be configured to store a different reference spectrum for each different type of anomaly. The types of anomalies include at least one of a scratch in the surface of the substrate, an unexpected film type, a bad pad rinse transition, or a bubble between the substrate and the polishing pad. The types of anomalies can include an unexpected film type, and the determination can be based on comparing the acoustic signals to prior measurements of acoustic signals generated by test substrates may include an expected film type and the polishing pad. The types of anomalies can include a bad pad rinse transition. The types of anomalies can include a bubble between the substrate and the polishing pad. The acoustic sensor can be arranged within a recess in a top surface of the platen.

In general, an aspect disclosed herein is a chemical mechanical polishing apparatus, including a platen to support a polishing pad; a carrier head to hold a surface of a substrate against the polishing pad; a motor to generate relative motion between the platen and the carrier head so as to polish an overlying layer on the substrate; a polishing liquid source to deliver a polishing liquid onto the polishing pad; a rinse liquid source to deliver a rinse liquid onto the polishing pad; an in-situ acoustic monitoring system including an acoustic sensor that receives acoustic energy from the substrate and the polishing pad; and a controller configured to detect a bad pad rinse transition based on measurements from the in-situ acoustic monitoring system.

In general, an aspect disclosed herein is a chemical mechanical polishing apparatus, a platen to support a polishing pad; a carrier head to hold a surface of a substrate against the polishing pad; a motor to generate relative motion between the platen and the carrier head so as to polish an overlying layer on the substrate; a polishing liquid source to deliver a polishing liquid onto the polishing pad; an in-situ acoustic monitoring system including an acoustic sensor that receives acoustic energy from the substrate and the polishing pad; and a controller configured to detect a bubble in the polishing liquid between the substrate and the polishing pad.

In general, an aspect disclosed herein is a polishing method, including contacting a surface of a substrate to a polishing surface of a polishing pad; generating relative motion between the substrate and the polishing pad; providing a liquid slurry onto the polishing surface of the polishing pad; monitoring acoustic energy from the substrate and the polishing pad using an in-situ acoustic monitoring system that includes an acoustic sensor; determine a presence of an abnormal acoustic event based on signals from the acoustic sensor; and identify a type of an anomaly based on acoustic signals from the in-situ acoustic monitoring system during the abnormal acoustic event.

Examples may include one or more of the following features. The method may include generating an alert based on the determination of the presence of the abnormal acoustic event. The method may include removing the surface of the substrate from contact with the polishing surface based on the determination of the presence of the abnormal acoustic event, or the identified type of anomaly. The method may include identifying the type of the anomaly as a bad pad rinse transition. The method may include identifying the type of the anomaly an improper film stack. The method may include identifying the type of the anomaly a bubble between the substrate and the polishing pad. The method may include removing the surface of the substrate from contact with the polishing surface based on the type of the anomaly.

Passively monitoring an acoustic signal in real-time facilitates detecting anomalies in the acoustic emission signal which can reduce production losses due to inferior substrates having scratches from bad pad rinse transitions. The detection of such events enables real-time process control to manage individual wafer polishing.

Monitoring the changes in the acoustic signal in real-time when an underlying layer is exposed facilitates differentiating detected events expected- or unexpected events, thereby increasing the production efficiency and reducing losses.

The details of one or more embodiments are set forth in the accompanying drawings and the description below. Other aspects, features and advantages will be apparent from the description and drawings, and from the claims.

### DESCRIPTION OF DRAWINGS

FIG. 1 is a schematic side view of a polishing system including an in-situ acoustic monitoring system.

FIG. 2 is a schematic top-view illustration of a substrate being polishing on a polishing pad with an example path the acoustic sensor follows during a polishing operation and an example acoustic signal generated while the sensor moves on the example path.

FIG. 3 is an illustration of an example acoustic signal and a segment corresponding to signal received from beneath the substrate.

FIG. 4 is an illustration of a bad pad rinse transition during planarization of a surface of a substrate.

FIG. 5 is a flow chart of a method of polishing that includes detection of abnormal events from acoustic signals.

In the figures, like references indicate like elements.

### DETAILED DESCRIPTION

One problem in CMP is that adverse process events, such as scratches, incorrect film stacks, or bad pad rinse transitions, are not detected in real-time. In some cases, the adverse event is not detected until the first wafers of a batch complete the process and yield loss is observed. This can result in significant time and cost losses. By passively monitoring an acoustic signal in real-time, it may be possible to detect discrete anomalies in the time-series acoustic emission signal which may indicate scratching of the substrate or bad pad rinse transitions. The detection of such events enables real-time process control to manage individual wafer polishing. It should be noted that these discrete anomalies differ, e.g., in spectrum, frequency, or both, from the acoustic energy generated by the friction between the polishing pad and the substrate, and from the change in the acoustic signal when an underlying layer is exposed. Moreover, the change in the acoustic signal when an underlying layer is exposed is expected, and thus also not an anomaly.

Another issue is the lack of real-time or on-tool means of detection of such adverse process events in a wafer polishing process. Further, existing solutions which rely on optical measurements of a surface of the wafer are expensive and require costly upgrades to installed systems. A passive acoustic monitoring system can reduce the costs associated with real-time monitoring and reduce complexity and maintenance for installed systems as compared to optics-based solutions.

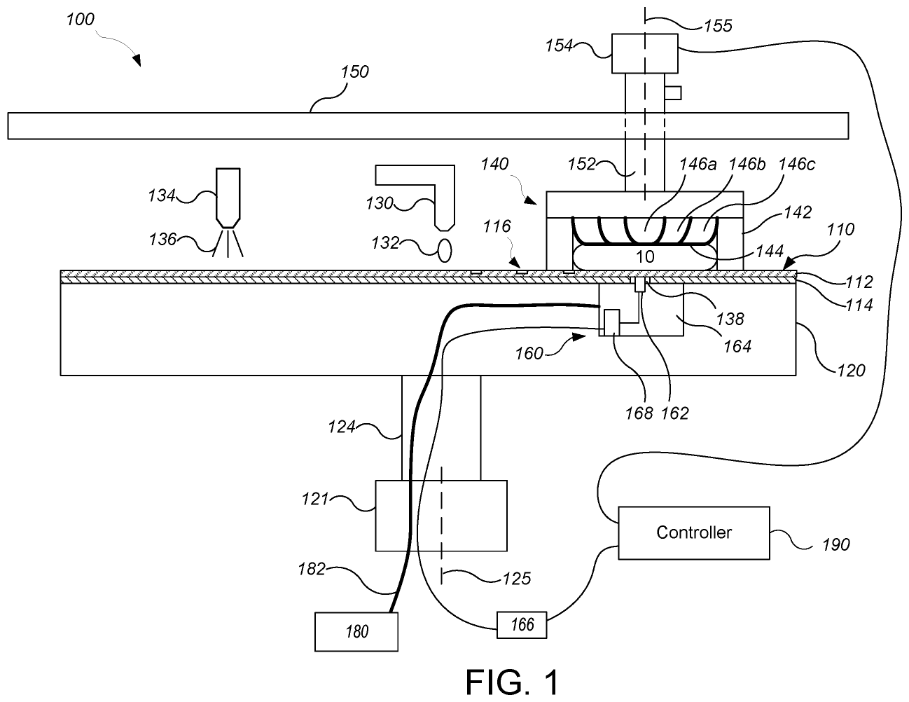

FIG. 1 illustrates an example of a polishing apparatus 100. The polishing apparatus 100 includes a rotatable disk-shaped platen 120 on which a polishing pad 110 is situated. The polishing pad 110 can be a two-layer polishing pad with an outer polishing layer 112 and a softer backing layer 114. The platen is operable to rotate about an axis 125. For example, a motor 121, e.g., a DC induction motor, can turn a drive shaft 124 to rotate the platen 120.

The polishing apparatus 100 can include a port 130 to dispense polishing liquid 132, such as abrasive slurry, onto the polishing pad 110. The polishing apparatus can also include a polishing pad conditioner to abrade the polishing pad 110 to maintain the polishing pad 110 in a consistent abrasive state.

The polishing apparatus 100 can include a rinse arm 134 to dispense rinsing liquid 136, such as water, onto the polishing pad 110. The rinsing liquid 136 is dispensed in between polishing events to clear polishing liquid 132 from the polishing layer 112. In some examples, the rinsing liquid 136 is dispensed at high pressure and/or is temperature-regulated (e.g., heated, or cooled) before being dispensed onto the polishing layer 112.

The polishing apparatus 100 includes at least one carrier head 140. The carrier head 140 is operable to hold a substrate 10 against the polishing pad 110. Each carrier head 140 can have independent control of the polishing parameters, for example pressure, associated with each respective substrate.

The carrier head 140 can include a retaining ring 142 to retain the substrate 10 below a flexible membrane 144. The carrier head 140 also includes one or more independently controllable pressurizable chambers defined by the membrane, e.g., three chambers 146a-146c, which can apply independently controllable pressurizes to associated zones on the flexible membrane 144 and thus on the substrate 10. Although only three chambers are illustrated in FIG. 1, there could be one or two chambers, or four or more chambers, e.g., five chambers.

The carrier head 140 is suspended from a support structure 150, e.g., a carousel or track, and is connected by a drive shaft 152 to a carrier head rotation motor 154, e.g., a DC induction motor, so that the carrier head can rotate about an axis 155. Optionally each carrier head 140 can oscillate laterally, e.g., on sliders on the structure 150, or by rotational oscillation of the carousel itself, or by sliding along the track. In a typical operation, the platen is rotated about its central axis 125, and each carrier head is rotated about its central axis 155 and translated laterally across the top surface of the polishing pad.

A controller 190, such as a programmable computer, is connected to the motors 121, 154 to control the rotation rate of the platen 120 and carrier head 140. For example, each motor can include an encoder that measures the rotation rate of the associated drive shaft. A feedback control circuit, which could be in the motor itself, part of the controller, or a separate circuit, receives the measured rotation rate from the encoder and adjusts the current supplied to the motor to ensure that the rotation rate of the drive shaft matches at a rotation rate received from the controller.

A position sensor, e.g., an optical interrupter connected to the rim of the platen or a rotary encoder, can be used to sense the angular position of the platen 120. This permits recording of the acoustic signal, or portions of the signal, to be measured when the sensor 162 is in proximity to the substrate, e.g., when the sensor 162 is below the carrier head or substrate.

The polishing apparatus 100 includes at least one in-situ acoustic monitoring system 160. In particular, the in-situ acoustic monitoring system 160 can be configured to detect acoustic emissions from the substrate 10. The in-situ acoustic monitoring system 160 includes one or more acoustic sensors 162 that each generate a signal, e.g., a digital or analog signal, representative of the acoustic waveform received at the sensor. Where there are multiple acoustic sensors, they can be installed at different locations on the upper platen 120, e.g., at equal angular intervals around the axis of rotation of the platen 120.

If positioned in the platen 120, the acoustic sensor 162 can be located at the center of the platen 120, e.g., at the rotation axis 125, at the edge of the platen 120, or at a midpoint (e.g., 5 inches from the axis of rotation for a 20-inch diameter platen).

In the implementation shown in FIG. 1, the acoustic sensor 162 is positioned in a recess 164 in the platen 120 and is positioned to receive acoustic energy from a side of the substrate closer to the polishing pad 110. As shown in FIG. 1, the acoustic sensor 162 can be extended through an aperture 138 in the backing layer 114 of the polishing pad 110 to directly contact a lower surface of the polishing layer 112. In some implementations, the acoustic sensor 162 is biased, e.g., by a spring, against the polishing layer 112. Alternatively, the acoustic sensor 162 can be secured, e.g., by an adhesive, to the lower surface of the polishing layer 112.

The acoustic sensor 162 can be connected by circuitry 168 to a power supply and/or other signal processing electronics 166 through a rotary coupling, e.g., a mercury slip ring. The signal processing electronics 166 can be connected in turn to the controller 190.

The in-situ acoustic monitoring system 160 is a passive acoustic monitoring system. The passive acoustic signals monitored by the acoustic sensor 162 can be in 50 kHz to 1 MHz range, e.g., 200 to 400 kHz, or 200 kHz to 1 MHz. For example, for monitoring of polishing of inter-layer dielectric (ILD) in a shallow trench isolation (STI), a frequency range of 225 kHz to 350 kHz can be monitored.

The signal from the sensor 162 can be amplified by a built-in internal amplifier with a gain of 40-60 dB. The signal from the sensor 162 can then be further amplified and filtered if necessary and digitized through an A/D port to a high-speed data acquisition board, e.g., in the electronics 166. Data from the sensor 162 can be recorded at a range from 1 to 10 MHz, e.g., 1-3 MHz or 6-8 MHz.

For the sensor 162, piezoelectric acoustic sensors capable of efficient high-frequency acoustic energy detection can be used.

In examples where a plurality of slurry-transport grooves 116 are formed in the top surface of the polishing layer 112 of the polishing pad 110, the aperture 138 can be aligned with a plateau region between the grooves 116, i.e., the aperture 138 is not directly below a groove.

In such examples, the acoustic sensor 162 is positioned in the platen 120 below the aperture 138 to receive acoustic signals from the substrate 10 that propagate through the polishing layer 112.

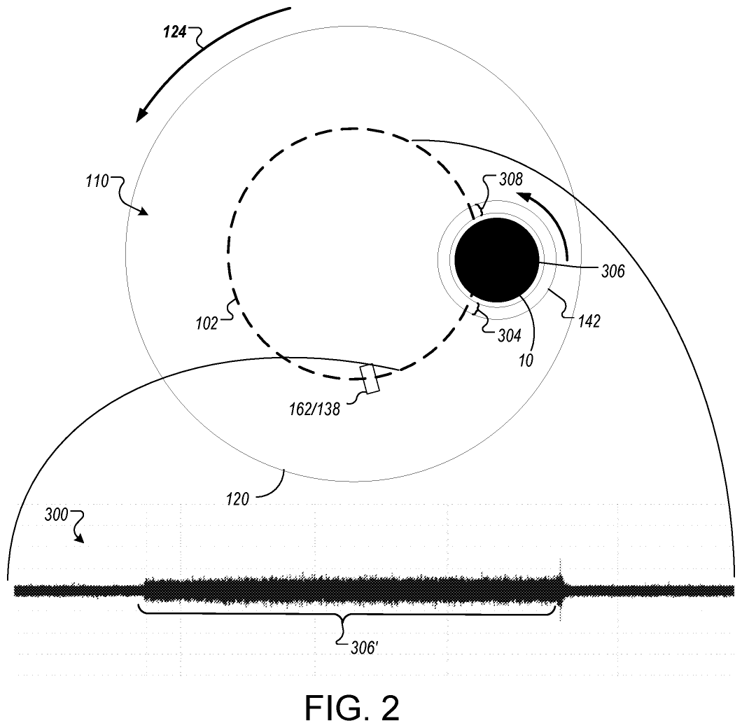

The acoustic monitoring system 160 monitors acoustic waves generated during polishing operations in which the sensor 162 travels a path that passes beneath the carrier head 140 and the substrate 10. Referring now to FIG. 2, an overhead view of the platen 120 and supported polishing pad 110, are shown with the substrate 10 being confined by the retaining ring 142. During a polishing operation, relative motion between the pad 110 and substrate 10 is generated by rotation of the platen 120, motion of the carrier head 140 confining the substrate 10, or a combination. As the platen 120 and supported pad 110 rotate around the axis 125, the sensor 162 follows a path 102 with respect to the visual reference frame of FIG. 2. As the sensor 162 follows the path 102, the sensor 162 travels beneath separate portions of the ring assembly 142 and the substrate 10. Path portion 306 corresponds to when the sensor 162 is under the substrate 10, and path portions 304 and 308 correspond to when the sensor 162 is under the retaining ring 142.

As the sensor 162 passes beneath the carrier head 140, the acoustic sensor 162 measures acoustic energy, e.g., the energy generated by contact between the retaining ring 142 or substrate 10 and the polishing pad 110 and aperture 138. In particular, the sensor 162 can measure compressive acoustic waves passing through the polishing pad 110. The acoustic energy that reaches the sensor 162 is primarily caused by the friction between the polishing pad 110 (including the aperture 138) and the particular component that is directly above the sensor 162, e.g., the retaining ring 142 or substrate 10. Information regarding the interaction between the substrate 10 and the polishing pad 110 can be obtained by analyzing the portion of the signal corresponding to path portion 306.

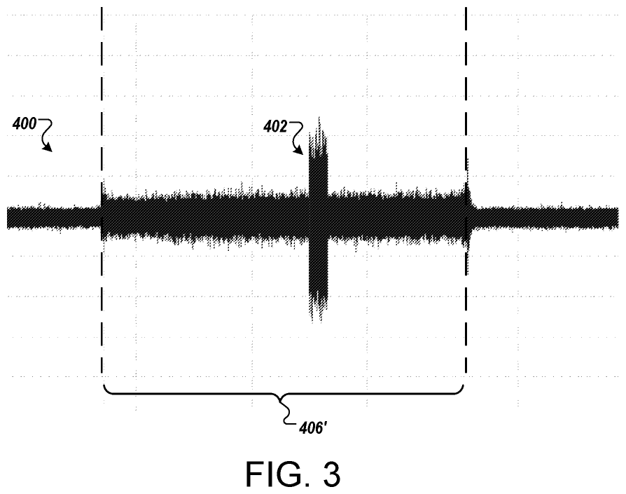

An exemplary time-series acoustic signal 300 is shown inset and an on-wafer portion 306′ of the signal 300 is denoted which corresponds to path portion 306. Referring to FIGS. 2 and 3, the acoustic monitoring system 160, e.g., the controller 190, processes the acoustic signal 300 and subdivides the acoustic signal 300 into segments. The acoustic monitoring system 160 can subdivide the acoustic signal 300 into segments according to one or more signal parameters, such as the amplitude of the acoustic signal 300. Some segments can correspond to portions of the signal which indicate abnormal acoustic events, such as portion 306′. The acoustic monitoring system 160 can monitor the amplitude of the acoustic signal 300, the position of the acoustic sensors 162, or both, to determine the presence and/or location of abnormal acoustic events.

In some implementations, the acoustic monitoring system 160 performs signal processing on the acoustic data generated by the acoustic sensor 162 to filter, e.g., de-noise, the acoustic data before communicating the acoustic data to the controller 190. The filtering can be a low-pass filter or running window average to smooth the measured signal from the sensor 162. In some examples, the acoustic monitoring system 160 generates an average value for the measured signal 300 within each segment.

Occasionally, the acoustic signal 300 includes an abnormal acoustic event, e.g., a deviation from an expected form of the acoustic signal 300, which can be detected by the controller 190 based on the received acoustic signal 300 from the acoustic signal sensor 162. Detected abnormal acoustic events can correspond to one or more examples of anomalies, such as defects in the substrate 10, or anomalies in the polishing process. Other examples of the anomalies include scratches on the polishing pad or wafer, carrier head 140 vibration, interrupted flow of polishing liquid 132, substrate 10 breakage, absence of a conditioning disk, presence, absence, or pressure of rinse liquid, or improper dechuck of the substrate 10 from the carrier head 140. Some of these examples would arise as an abnormal acoustic event during monitoring when the sensor 162 is not under the carrier head 140.

The acoustic monitoring system 160 communicates the acoustic signal 300 to the controller 190. The controller 190 processes the received acoustic signal 300 to determine the presence of an abnormal acoustic event by comparing a value of a characteristic of the signal 300 to a predetermined threshold value. Examples of a characteristic of the signal include an average amplitude of the segment of the signal, the maximum or minimum amplitude within the segment of the signal, the intensity at some frequency in the frequency spectrum of segment of the signal, the total power in some bandwidth range of the frequency spectrum of segment of the signal, or the location (frequency) of a peak or valley in the frequency spectrum of segment of the signal. In some implementations, the controller 190 determines alternative data parameters, such as a derivative, an average, an integral, a standard deviation, or a variance of the acoustic signal 300, or of one or more of the segments of the acoustic signal 300. In some examples, the controller 190 compares the received signal 300 to one or more stored test signals which were generated by test substrates during different polishing processes. The test signals can be previously determined to contain no abnormal acoustic events and therefore be considered successful polishing operations.

In FIG. 3 an exemplary time-series acoustic signal 400, which can be an example of signal 300, is shown having an on-wafer segment 406′ which was determined by the controller 190. The segment 406′ is determined by the controller 190 based on the increased average amplitude from the surrounding acoustic signal 400. The on-wafer segment 406′ includes an exemplary abnormal acoustic event 402. The abnormal acoustic event 402 is a portion of the acoustic signal 400 having an instantaneous and/or average amplitude substantially above the surrounding acoustic signal 400, though other abnormal acoustic events may have different acoustic parameters when compared to the acoustic signal 400.

In an example, the anomaly is an incorrect film stack or incorrect film type in the substrate 10. A substrate 10 includes a series of sequentially deposited conductive, semiconductive, or insulative layers on a silicon wafer appearing in an expected order. If the deposited layers were erroneously deposited out of sequence, partially deposited, or both, the signal 300 can include an abnormal acoustic event which corresponds with an incorrect film stack.

In some examples, the abnormal acoustic event can be determined at the beginning of polishing. As one example, in the event of a missing deposition layer or substantial deposition sequence error, the difference is detected immediately as an abnormal acoustic event since the observed intensity is outside the typically observed range at the start of polish. Other acoustic events can be detected from evolution of the signal at later times.

In an example, the anomaly is a defect of the substrate 10 such as a physical defect in the substrate 10, e.g., the surface, which adversely affects the form or function of the substrate 10 such as a scratch, crack, chip, missing portion of a layer, or a combination. A defect in the substrate 10 can appear as a signal fragment having an increased amplitude or increased power in a particular frequency range in a transformed signal. The defect, e.g., a scratch, can be a transitory, single event, such as a particulate trapped beneath the substrate 10 for a single pass, or can be a repeatedly detectable event such as a continuous series of scratches.

The anomaly can be a bubble, e.g., trapped or entrained gas, between the substrate 10 and the pad 110 which adversely affects the polishing process and reduces surface uniformity. A bubble can appear as a signal fragment having an increased amplitude, decreased power, or both, in a particular frequency range.

The anomaly can be a bad pad rinse transition. At the end of a polishing process, the substrate 10 is removed from contact with the pad 110 and the polishing liquid, e.g., the slurry, is rinsed off the surface of the polishing layer 112. Such a process helps ensure a uniform slurry composition on a wafer-to-wafer basis and removes contaminations such as particulates polished from the surface of the substrate 10 to reduce defects. In one example, unusual power amplitude or variance detected at one or more locations on the wafer are indicative of slurry rather than water indicate that some parts of the wafer include quantities of slurry, e.g., are not fully rinsed.

In general, the substrate 10 is removed from contact by lifting the carrier head 140 while the substrate 10 is chucked to the flexible membrane 144. The rinse arm 134 supplies the rinsing liquid 136 to the outer polishing layer 112 and removes contaminated slurry. Once a sufficient amount of the contaminated slurry is removed, e.g., substantially all of the slurry, the rinse arm 134 stops supplying the rinsing liquid 136.

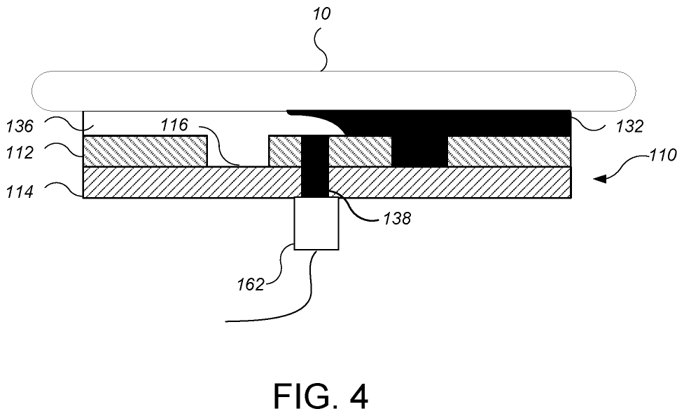

With reference to FIG. 4, the carrier head 140 brings the substrate 10 into contact with the pad 110 following a rinse transition. The dimensions are exaggerated for clarity, in general the substrate 10 is in direct contact with the upper surface of the pad 110 and the rinsing liquid 136 and polishing liquid 132 form a thin liquid layer as well as inhabit the slurry-transport grooves 116. If the polishing liquid 132 has not been sufficiently removed and some polishing liquid 132 remains between the substrate 10 and the outer polishing layer 112, this is termed as a “bad pad rinse transition” which should be corrected before continuing the polishing process. FIG. 4 shows both polishing liquid 132 and rinsing liquid 136 between the substrate 10 and the outer polishing layer 112 which results in a different acoustic signal than if either the polishing liquid 132 or the rinsing liquid 136 were present. A bad pad rinse transition can appear as a signal fragment in which the signal power spectrum fluctuates outside of anticipated boundaries. From the signal, the controller 190 can determine that a type of liquid present between the substrate 10 and the polishing layer 112 is an incorrect type of liquid, e.g., when polishing liquid 132 is present following a pad rinse.

The controller 190 can store in memory or attached storage device a catalog (e.g., a table, or index) of anomalies detectable by the in-situ acoustic monitoring system 160. In addition, for each of the detectable anomalies, the controller 190 stores one or more associated criteria, e.g., a frequency spectrum representative of the spectrum that occurs for the respective anomaly. The controller 190 processes the acoustic signal 300 to identify the presence of one or more anomalies. For example, the controller 190 compares the determined abnormal acoustic event to detectable anomaly entries in the catalog. In one example, the controller 190 processes the acoustic signal 300 to produce a detected frequency spectrum and compares such to the stored anomaly frequency spectrums. If the detected frequency spectrum sufficiently matches criterion of stored anomaly frequency spectrums in the catalog, the controller 190 determines the presence of associated anomaly. The controller 190 can then control the apparatus 100 responsive to the determination including communicating one or more alerts for display to a user, terminating a polishing process, or combinations thereof.

The criterion associated with the anomalies can be determined through experimentation, e.g., polishing one or more test wafers which may include known anomalies, detecting the present anomaly based on the received signal departing from a baseline signal received from test wafers known to be free of defects or anomalies, and recording the differences in the received signals to determine the type of anomaly with the associated differences.

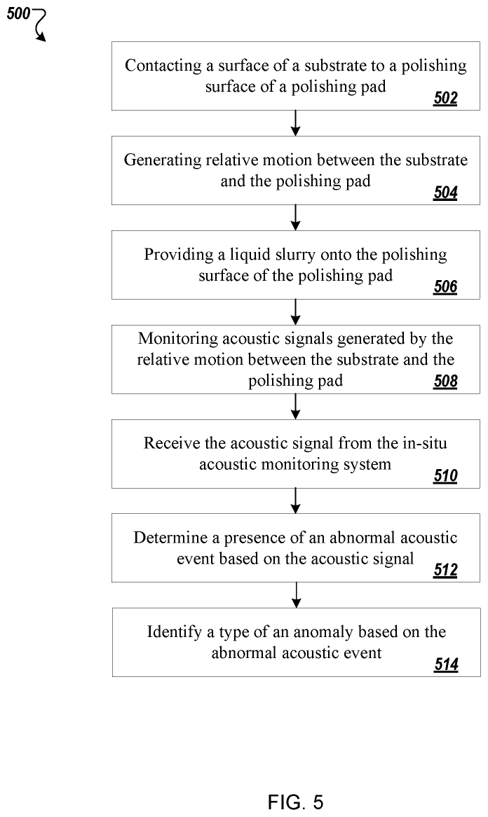

Disclosed herein is a method 500 in FIG. 5 for polishing and acoustic monitoring to detect anomalies.

A surface of the substrate is contacted to a polishing surface of the polishing pad (step 502). A substrate 10 is provided and installed, e.g., chucked, to a carrier head. The carrier head contacts a surface of the substrate a polishing surface, e.g., polishing layer 112 of the polishing pad.

Motion is generated between the substrate and the polishing pad (step 504). For example, the polishing pad is supported by a rotatable platen, e.g., platen 120, which is configured to rotate about a central rotational axis, e.g., axis 125. In some examples, the carrier head is also rotatable about a central rotational axis, e.g., central axis 155, which can induce rotation in the substrate when the carrier head rotates. The relative motion of the carrier head and/or the platen generates relative motion between the substrate and the pad.

A liquid slurry, e.g., polishing liquid 132, is provided onto the polishing surface (step 506). A liquid slurry port, e.g., port 130, provides liquid slurry to the polishing surface and in some examples can be heated and/or cooled before being provided.

Acoustic energy is monitored by a sensor of an acoustic monitoring system, e.g., sensor 162 of acoustic monitoring system 160 (step 508). The sensor can be installed in a recess of the platen and receives the generated acoustic signals through the polishing layer 112.

The signals representative of the acoustic energy are received by the controller from the sensor of the acoustic monitoring system (step 510). When the acoustic sensor travels below the substrate, the received acoustic signals are indicative of the polishing process and can include information on the liquid between substrate and the pad. The controller performs one or more processes to determine whether an abnormal acoustic event is present in the received acoustic signals.

The controller determines a presence of an abnormal acoustic event based on the received acoustic signal (step 512), e.g., abnormal acoustic event 402. The controller performs signal processing to determine the presence of the abnormal acoustic event, such as determining an average amplitude, the maximum or minimum amplitude, the intensity at some frequency in the frequency spectrum, the total power, or the location (frequency) of a peak or valley in the frequency spectrum. The controller may determine alternative data parameters, such as a derivative, an average, an integral, a standard deviation, or a variance of the acoustic signal to determine the presence of the abnormal acoustic event. The abnormal acoustic event can be indicative of an anomaly in the polishing process.

The controller identifies a type of an anomaly based on the abnormal acoustic event (step 514). The controller includes a catalog of types of abnormal acoustic events which correlates each type of abnormal acoustic event with one or more associated anomalies in the polishing process. Examples anomalies in the polishing process include gas bubbles between the substrate and the polishing layer, bad rinse transitions, or improper film type exposed on the surface of the substrate. Each anomaly can correspond to a different type of determined abnormal acoustic event.

An alert can be generating based on the determination of the presence of the abnormal acoustic event. Examples of an alert the apparatus can generate include a text-based message, or an audio/visual cue communicated to a local or networked device, such as a display, or a computer.

The substrate can be removed from contact with the polishing surface based on the presence of the abnormal acoustic event, or the identified type of anomaly. In an example, the type of anomaly is a bad pad rinse transition, the controller commands the carrier head to remove the substrate from contact with the polishing surface, and the rinse supply arm to provide the rinsing liquid to the pad. In another example, the type of anomaly is an improper film stack, and the controller generates an alert and commands the carrier head to remove the substrate from contact with the pad.

In some examples, the type of anomaly is the presence of slurry before initiating a new polishing step. Used slurry that is present before initiation of a new polishing step on a new substrate can negatively affect the polishing process due to the presence of particulates in the slurry from previous polishings. Therefore, detecting the presence of the used slurry facilitates performing a rinse step before the new polishing process begins.

If used slurry is detected, the rinse arm 134 dispenses the rinsing liquid 136 a first or additional times until the controller 190 determines that the used slurry is no longer present on the polishing layer 112.

While this specification contains many details, these should not be construed as limitations on the scope of what may be claimed, but rather as descriptions of features specific to particular examples. Certain features that are described in this specification in the context of separate implementations can also be combined. Conversely, various features that are described in the context of a single implementation can also be implemented in multiple embodiments separately or in any suitable subcombination.

What is claimed is:

1. A chemical mechanical polishing apparatus, comprising:
a platen to support a polishing pad;
a carrier head to hold a surface of a substrate against the polishing pad;
a motor to generate relative motion between the platen and the carrier head so as to polish an overlying layer on the substrate;
an in-situ acoustic monitoring system including an acoustic sensor that receives acoustic energy from the substrate and the polishing pad; and
a controller configured to
detect an abnormal acoustic event based on measurements from the in-situ acoustic monitoring system, and
determine a type of anomaly based on signals measured by the in-situ acoustic monitoring system during the abnormal acoustic event.

2. The apparatus of claim 1, wherein the controller detects the abnormal acoustic event based on comparison of the signal to prior measurements of acoustic signals generated by friction between test substrates and the polishing pad.

3. The apparatus of claim 1, wherein the detection of the abnormal acoustic event is based on the controller determining a power spectrum of the acoustic signals; determining a difference between the power spectrum and a reference power spectrum stored in a storage device of the apparatus; and detection the abnormal acoustic event based on the difference.

4. The apparatus of claim 1, wherein the controller is configured to store a catalog that includes a plurality of types of anomalies and at least one criterion for each type of anomaly.

5. The apparatus of claim 4, wherein the at least one criterion includes a degree of similarity to a reference spectrum representative of the type of anomaly.

6. The apparatus of claim 5, wherein the controller is configured to store a different reference spectrum for each different type of anomaly.

7. The apparatus of claim 4, wherein the types of anomalies include at least one of a scratch in the surface of the substrate, an unexpected film type, a bad pad rinse transition, or a bubble between the substrate and the polishing pad.

8. The apparatus of claim 7, wherein the types of anomalies include an unexpected film type, and the determination is based on comparing the acoustic signals to prior measurements of acoustic signals generated by test substrates comprising an expected film type and the polishing pad.

9. The apparatus of claim 7, wherein the types of anomalies include a bad pad rinse transition.

10. The apparatus of claim 7, wherein the types of anomalies include a bubble between the substrate and the polishing pad.

11. The apparatus of claim 1, wherein the acoustic sensor is arranged within a recess in a top surface of the platen.

12. A chemical mechanical polishing apparatus, comprising:
a platen to support a polishing pad;
a carrier head to hold a surface of a substrate against the polishing pad;
a motor to generate relative motion between the platen and the carrier head so as to polish an overlying layer on the substrate;
a polishing liquid source to deliver a polishing liquid onto the polishing pad;
a rinse liquid source to deliver a rinse liquid onto the polishing pad;
an in-situ acoustic monitoring system including an acoustic sensor that receives acoustic energy from the substrate and the polishing pad; and
a controller configured to detect a bad pad rinse transition based on measurements from the in-situ acoustic monitoring system.

13. A chemical mechanical polishing apparatus, comprising:
a platen to support a polishing pad;
a carrier head to hold a surface of a substrate against the polishing pad;
a motor to generate relative motion between the platen and the carrier head so as to polish an overlying layer on the substrate;
a polishing liquid source to deliver a polishing liquid onto the polishing pad;
an in-situ acoustic monitoring system including an acoustic sensor that receives acoustic energy from the substrate and the polishing pad; and
a controller configured to detect a bubble in the polishing liquid between the substrate and the polishing pad.

14. A polishing method, comprising:
contacting a surface of a substrate to a polishing surface of a polishing pad;
generating relative motion between the substrate and the polishing pad;
providing a liquid slurry onto the polishing surface of the polishing pad;
monitoring acoustic energy from the substrate and the polishing pad using an in-situ acoustic monitoring system that includes an acoustic sensor;
determine a presence of an abnormal acoustic event based on signals from the acoustic sensor; and
identify a type of an anomaly based on acoustic signals from the in-situ acoustic monitoring system during the abnormal acoustic event.

15. The method of claim 14, further comprising generating an alert based on the determination of the presence of the abnormal acoustic event.

16. The method of claim 14, further comprising removing the surface of the substrate from contact with the polishing surface based on the determination of the presence of the abnormal acoustic event, or the identified type of anomaly.

17. The method of claim 14, further comprising identifying the type of the anomaly as a bad pad rinse transition.

18. The method of claim 14, further comprising identifying the type of the anomaly an improper film stack.

19. The method of claim 14, further comprising identifying the type of the anomaly a bubble between the substrate and the polishing pad.

20. The method of claim 14, further comprising removing the surface of the substrate from contact with the polishing surface based on the type of the anomaly.
